(19) United States
(12) Patent Application Publication
(10) Pub. No.: US 2020/0035885 A1
(43) Pub. Date: Jan. 30, 2020

(54) DIELECTRIC MIRROR FOR BROADBAND IR LEDS

(71) Applicant: Lumileds LLC, San Jose, CA (US)

(72) Inventor: Charles SCHRAMA, San Jose, CA (US)

(73) Assignee: Lumileds LLC, San Jose, CA (US)

(21) Appl. No.: 16/049,519

(22) Filed: Jul. 30, 2018

(51) Int. Cl. H01L 33/60; H01L 33/50

(52) U.S. Cl. CPC H01L 33/60; H01L 33/505; H01L 2933/0058; H01L 2933/0041; H01L 2933/005

(57) ABSTRACT

An LED package comprising an LED pump die, a phosphor and a dielectric mirror is described. The LED pump die emits light within a first wavelength range. The phosphor encapsulates the LED pump die and has characteristics that convert light within the first wavelength range to light within a second wavelength range, the second wavelength range being higher than the first wavelength range. The dielectric mirror is configured to reflect light within the first wavelength range and transmit light within the second wavelength range. As such, the unconverted light within the first wavelength that is emitted from the LED package is recycled back into the LED package.

### FIELD OF INVENTION

The present disclosure relates to LED packages, and more particularly, to infrared (IR) LED packages.

### BACKGROUND

A common method for analyzing the composition of organic substances is IR radiation. IR radiation or near IR radiation excites vibrational modes in the material to be tested, resulting in the characteristic absorption bands.

Current broadband IR LED packages comprise an LED pump die which emits UV and/or visible light and a phosphor overlaying the LED pump die to convert the UV and/or visible light into IR radiation. However, the conversion efficiency from UV and/or visible light to IR radiation is relatively low in these packages and a significant part of the UV and/or visible light emitting from the LED pump die leaves the package unconverted. As such, the conversion efficiency of these LED packages is not optimal and unwanted UV and/or visible light appears in the application.

### SUMMARY

The present disclosure describes an LED package that includes an LED pump die, a phosphor, and a dielectric mirror. The LED pump die emits light within a first wavelength range. The phosphor encapsulates the LED pump die and has characteristics which convert light within the first wavelength range to light within a second wavelength range. The first wavelength range may be within the ultraviolet (UV) and/or visible portions of the spectrum. The second wavelength range may be light within the IR portion of the spectrum. The dielectric mirror reflects light within the first wavelength range and transmits light within the second wavelength range. The dielectric mirror is placed such that the light within the first wavelength range that is emitted from the LED package is recycled back into the LED package and the light within the second wavelength range that is emitted from the LED package is transmitted.

### BRIEF DESCRIPTION OF THE DRAWINGS

FIG. 1 is a sectional view of an LED package of the prior art.

FIG. 2 is a graph showing the spectral radiant flux of light leaving an LED package of the prior art.

FIG. 3 is a sectional view of the LED package of the present disclosure.

FIG. 4 is a sectional view of an alternate embodiment of the LED package of the present disclosure.

FIG. 5 is a graph showing the spectral radiant flux of light leaving the LED package of the present disclosure.

FIG. 6 shows a flow chart of a method of producing an LED package of the present disclosure.

### DETAILED DESCRIPTION OF THE PREFERRED EMBODIMENTS

Broadband IR LEDs can be used in various applications, including but not limited to IR spectroscopy and security cameras. In general, broadband IR LED packages comprise an LED pump die which emits UV and/or visible light and a phosphor overlaying the LED pump die to convert the UV and/or visible light into IR radiation. However, the conversion of UV and/or visible light to IR radiation in these IR LED packages is relatively low.

Dichroic mirrors are a type of dielectric mirror typically used for incandescent lamps. Visible light (cold) and IR (warm) light are separated, such that only the visible light is reflected. The LED package of the present disclosure mirror uses a dichroic mirror to reflect unconverted UV and/or visible light emitted from an LED package back into the package so that it may be converted into IR light.

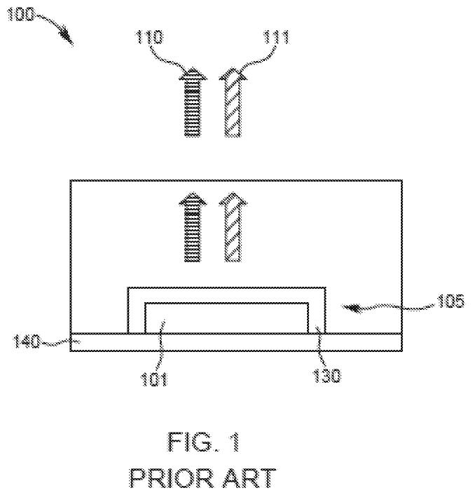

FIG. 1 illustrates an LED package 100 of the prior art. The LED package of the prior art comprises an LED structure 105 comprising an LED pump die 101 and a phosphor layer 130, and a substrate 140. The LED pump die 101 is disposed on the substrate 140 and emits light within a first wavelength range 111. The first wavelength range may be within the ultraviolet (UV) and/or visible portions of the spectrum. For example, the first wavelength range may be 350-500 nm. The phosphor 130 overlays the LED pump die 101 and converts the light within the first wavelength range 111 emitted from the LED pump die 101 to light within a second wavelength range 110. The second wavelength range 110 is higher than the first wavelength range 111. The second wavelength range may be within the IR portion of the spectrum. For example, the second wavelength range may be 600-2500 nm. However, light within the first wavelength range 111 may escape the LED package 100 unconverted, as illustrated in FIG. 1. This may result in unwanted UV and/or visible light to be present in the final application.

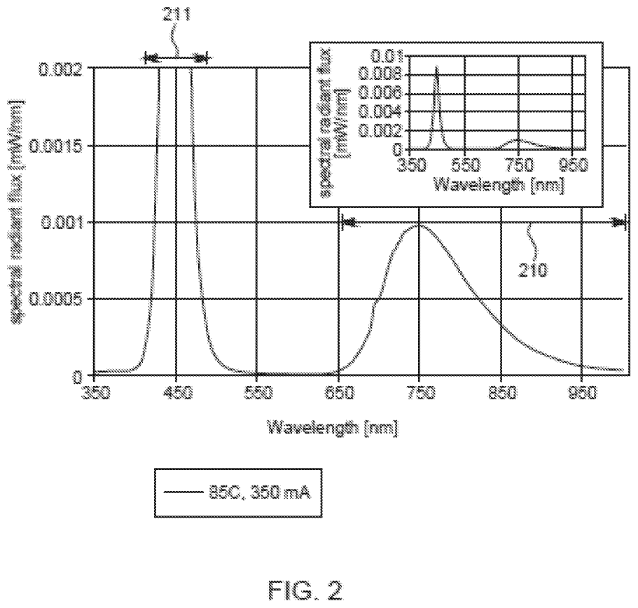

FIG. 2 is a graph showing the spectral radiant flux (mW/nm) of light leaving an LED package 100 of the prior art illustrated in FIG. 1. As illustrated in FIG. 2, a significant portion of light within a first wavelength range 211 of approximately 350-500 nm escapes the package unconverted and the amount of light within a second wavelength range 211 of approximately 650-1 mm, i.e. converted light, is relatively low. This graph illustrates the relatively low conversion efficiency of LED packages of the prior art.

The LED package of the present disclosure comprises an LED pump die, a phosphor which substantially encapsulates the LED pump die, and at least one dielectric mirror.

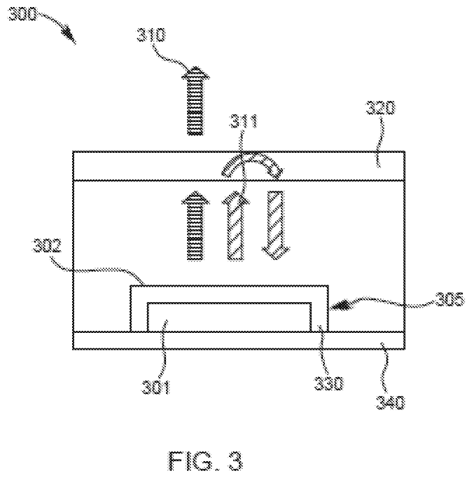

FIG. 3 illustrates an embodiment of the LED package 300 of the present disclosure. The LED package 300 comprises an LED structure 305 comprising an LED pump die 301 and a phosphor 330, a substrate 340, and a dielectric mirror 320. In the first embodiment, the LED pump die 301 is mounted on a support substrate 340. The LED pump die 301 emits light within a first wavelength range 311. In one embodiment, the first wavelength range 311 is within the UV and/or visible portions of the spectrum. In a further embodiment, the first wavelength range 311 is approximately 350-500 nm. In further embodiment, the LED pump die 301 is a blue LED pump die which emits blue light.

A phosphor 330 substantially encapsulates the LED pump die 301. The phosphor 330 has characteristics which convert light within the first wavelength range 311 to light within a second wavelength range 310. The second wavelength range 310 is higher than the first wavelength range 311. In one embodiment, the second wavelength range 310 is within the IR portion of the spectrum. For example, in an embodiment where the first wavelength range 311 is approximately 350-500 nm, the second wavelength range 310 may be approximately 600-2500 nm, which is within the IR portion of the spectrum.

The LED package 300 of the present disclosure further comprises at least one dielectric mirror 320. The at least one dielectric mirror 320 is configured to reflect light within the first wavelength range 311 and transmit light within the second wavelength range 310. For example, in an embodiment where the first wavelength range 311 is approximately 350-500 nm and the second wavelength range 310 is approximately 600-2500 nm, the dielectric mirror 320 reflects light having a wavelength of approximately 350-500 nm and transmits light having a wavelength of approximately 600-2500 nm.

The at least one dielectric mirror 320 is placed such that light within the first wavelength range 311 that is emitted from the LED package 300 is reflected back into the LED package 300. As such, the unconverted light that escapes from the package may be recycled back into the package for conversion. Light within the second wavelength range 310 is able to escape from the package, since the dielectric mirror 320 transmits light within the second wavelength range 310.

In one embodiment, a majority of the light within the first wavelength range 311 and the second wavelength range 310 is emitted from a top surface 302 of an LED structure 305. In this embodiment, the dielectric mirror 320 is placed over the top surface 302 of the LED structure 305. As such, the light within the first wavelength range 311 and the light within the second wavelength range 310 that is emitted from the top surface 302 of the LED structure 305 interacts with the dielectric mirror 320. As illustrated in FIG. 3, the light within the first wavelength range 311 that is emitted from the LED package 300 is reflected back into the LED package 300 and light within the second wavelength range 310 escapes from the package. The light within the first wavelength range 311 that is reflected back into the LED package 300 may re-enter the package to be converted to light within the second wavelength range 310. This may result in improved conversion efficiency from light within the first wavelength range 311 to light within the second wavelength range 310.

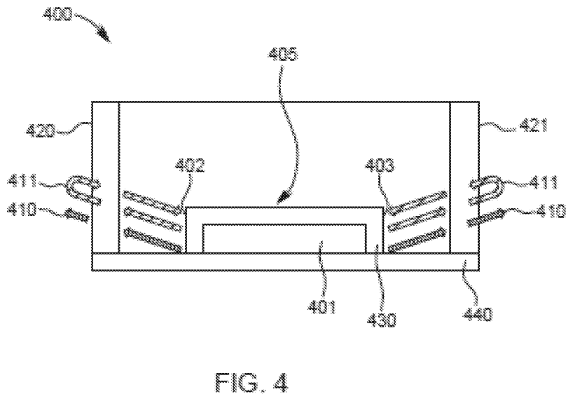

FIG. 4 illustrates an alternative embodiment of the LED package 400 of the present disclosure comprising an LED structure 405. In the alternative embodiment, the LED structure 405 comprises a laterally emitting LED pump die 401 and a phosphor 430. The laterally emitting LED pump die 401 is mounted on a support substrate 440. The laterally emitting LED pump die 401 emits light within a first wavelength range 411. In one embodiment, the first wavelength range 411 is within the UV and/or visible portions of the spectrum. In a further embodiment, the first wavelength range 411 is approximately 350-500 nm. In further embodiment, the LED pump die 401 is a blue LED pump die which emits blue light.

A phosphor 430 substantially encapsulates the laterally emitting LED pump die 401. The phosphor 430 has characteristics which convert light within the first wavelength range 411 to light within a second wavelength range 410. The second wavelength range 410 is higher than the first wavelength range 411. In one embodiment, the second wavelength range 410 is within the IR portion of the spectrum. For example, in an embodiment where the first wavelength range 411 is approximately 350-500 nm, the second wavelength range 410 may be approximately 600-2500 nm.

The LED package 400 further comprises at least one dielectric mirror 420. The at least one dielectric mirror 420 is configured to reflect light within the first wavelength range 411 and transmit light within the second wavelength range 410. For example, in an embodiment where the first wavelength range 411 is approximately 350-500 nm and the second wavelength range 410 is approximately 600-2500 nm, the dielectric mirror 420 reflects light having a wavelength of approximately 350-500 nm and transmits light having a wavelength of approximately 600-2500 nm.

The at least one dielectric mirror 420 is placed such that light within the first wavelength range 411 that is emitted from the LED package 400 is reflected back into the LED package 400. As such, the unconverted light that escapes from the package may be recycled back into the package for conversion. Light within the second wavelength range 410 is able to escape from the package, since the dielectric mirror 420 transmits light within the second wavelength range 410.

In the embodiment illustrated in FIG. 4, a majority of the light is emitted from a first side surface 402 of the LED structure 405 and a second side surface 403 of the LED structure 405. As such, a first dielectric mirror 420 is placed adjacent to the at least one side surface 402 of the LED structure 405. In a preferred embodiment, the LED package 400 further comprises a second dielectric mirror 421 that is adjacent a second side surface 403 of the LED structure 405 and opposite the first dielectric mirror 420. Similar to the first dielectric mirror 420, the second dielectric mirror 421 is configured reflect light within the first wavelength range 411 and transmit light within the second wavelength range 410. For example, in an embodiment where the first wavelength range 411 is approximately 350-500 nm and the second wavelength range 410 is approximately 600-2500 nm, the dielectric mirror 420 reflects light having a wavelength of approximately 350-500 nm and transmits light having a wavelength of approximately 600-2500 nm.

As such, a majority of the light within the first wavelength range 411 and a majority of the light within the second wavelength range 410 that is emitted from a first side 402 of the LED structure 405 interacts with the first dielectric mirror 420. As illustrated in FIG. 4, the light within the first wavelength range 411 that is emitted from the first side 402 of the LED structure 405 is reflected back into the LED package 400 and light within the second wavelength range 410 escapes the package 400. The light within the first wavelength range 411 that is reflected back into the LED package 400 may re-enter the package to be converted to light within the second wavelength range 410. This may result in improved conversion efficiency from light within the first wavelength range 411 to light within the second wavelength range 410.

In a preferred embodiment with both a first dielectric mirror 420 and a second dielectric mirror 420, a majority of the light within the first wavelength range 411 and a majority of the light within the second wavelength range 410 that is emitted from the second side 403 of the LED structure 405 interacts with the second dielectric mirror 421. As such, the light within the first wavelength range 411 and the light within the second wavelength range 410 that is emitted from the second side 403 of the LED structure 405 interacts with the second dielectric mirror 421. As illustrated in FIG. 4, the light within the first wavelength range 411 that is emitted from the second side 403 of the LED structure 405 is reflected back into the LED package 400 and light within the second wavelength range 410 escapes the package 400. The light within the first wavelength range 411 that is reflected back into the LED package 400 may re-enter the package to be converted to light within the second wavelength range 410. This may result in improved conversion efficiency from light within the first wavelength range 411 to light within the second wavelength range 410.

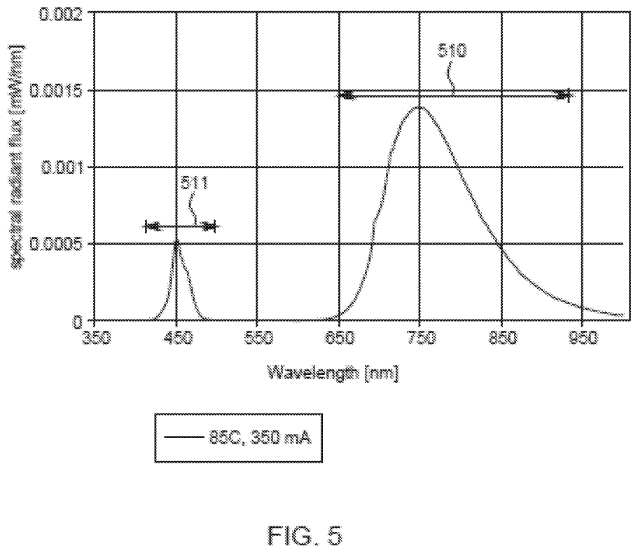

FIG. 5 is a graph showing the spectral radiant flux (mW/nm) of light leaving an LED package of the present disclosure. As illustrated in FIG. 5, the spectral radiant flux of light within a first wavelength range 510 of approximately 350-500 nm that is emitted from the LED package of the present disclosure is significantly less than that of the spectral radiant flux of the light within the first wavelength range 210 leaving the LED package of the prior art, illustrated in FIG. 2. More light within a second wavelength range 510 of approximately 650-1 mm is emitted from the package of the present disclosure, as compared to the amount of light within the second wavelength range 210 that is emitted from the LED package of the prior art as illustrated in FIG. 2. As such, the LED package of the present disclosure has better efficiency and significantly reduces or eliminates the amount of unwanted light in the application.

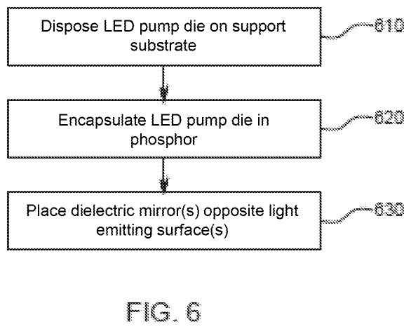

FIG. 6 shows a flow chart of a method of producing an LED package of the present disclosure. At step 610, an LED pump die is disposed on a support substrate. The LED pump die emits light within a first wavelength range. In one embodiment, the first wavelength range is within the UV and/or visible portions of the spectrum. In a further embodiment, the first wavelength range is approximately 350-500 nm. In further embodiment, the LED pump die is a blue LED pump die which emits blue light.

Next, the LED pump die is encapsulated in a phosphor at step 620 to create an LED structure. The phosphor has characteristics which convert light within the first wavelength range to light within a second wavelength range. The second wavelength range is higher than the first wavelength range. In one embodiment, the second wavelength range is within the IR portion of the spectrum. For example, in an embodiment where the first wavelength range 311 is approximately 350-500 nm, the second wavelength range 310 may be approximately 600-2500 nm.

Finally, at step 630, at least one dielectric mirror is placed opposite a surface of the LED structure from which light is emitted. For example, if a majority of the light is emitted from a top surface of the LED structure the at least one dielectric mirror is placed over a top surface of the LED structure. If the LED structure is laterally emitting, then a dielectric mirror may be placed on the side surfaces of the LED structure which emit light.

The at least one dielectric mirror is configured to reflect light within the first wavelength range and transmit light within the second wavelength range. For example, in an embodiment where the first wavelength range is approximately 350-500 nm and the second wavelength range is approximately 600-2500 nm, the dielectric mirror reflects light having a wavelength of approximately 350-500 nm and transmits light having a wavelength of approximately 600-2500 nm.

The at least one dielectric mirror is placed such that light within the first wavelength range that is emitted from the LED package is reflected back into the LED package. As such, the unconverted light that escapes from the package may be recycled back into the package for conversion. Light within the second wavelength range is able to escape from the package, since the dielectric mirror transmits light within the second wavelength range. This may result in improved conversion efficiency from light within the first wavelength range to light within the second wavelength range.

Having described the invention in detail, those skilled in the art will appreciate that, given the present disclosure, modifications may be made to the invention without departing from the spirit of the inventive concepts described herein. Therefore, it is not intended that the scope of the invention be limited to the specific embodiments illustrated and described.

What is claimed is:

1. An LED package comprising:
an LED structure comprising:
an LED pump die that emits light within a first wavelength range; and
a phosphor that encapsulates the LED pump die, the phosphor having characteristics that convert light within the first wavelength range to light within a second wavelength range, the second wavelength range being higher than the first wavelength range; and
a dielectric mirror, the dielectric mirror being configured to reflect light within the first wavelength range and transmit light within the second wavelength range.

2. The LED package of claim 1, wherein the first wavelength range is 350-500 nm.

3. The LED package of claim 2, wherein the second wavelength range is 600-2500 nm.

4. The LED package of claim 1, wherein the dielectric mirror is placed opposite a surface of the LED pump die from which light is emitted.

5. The LED package of claim 1, wherein a majority of the light emitted from the LED is emitted from a first surface of the LED pump die.

6. The LED package of claim 5, wherein the dielectric mirror is placed over the first surface LED pump die.

7. The LED package of claim 1, wherein the dielectric mirror reflects light within the first wavelength range emitted from the LED package back into the LED package.

8. An LED package comprising:
an LED structure comprising:
a laterally emitting LED pump die that emits light within a first wavelength range;
a phosphor that encapsulates the laterally emitting LED pump die, the phosphor having characteristics that convert light within the first wavelength range to light within a second wavelength range, the second wavelength range being higher than the first wavelength range; and
a first dielectric mirror that is adjacent to a first side surface of the laterally emitting LED pump die, the first dielectric mirror being configured to reflect light within the first wavelength range and transmit light within the second wavelength range.

9. The LED package of claim 8, wherein the first wavelength range is 350-500 nm.

10. The LED package of claim 9, wherein the second wavelength range is 600-2500 nm.

11. The LED package of claim 8, wherein the first dielectric mirror reflects light within the first wavelength range emitted from the LED package back into the LED package.

12. The LED package of claim 11, further comprising a second dielectric mirror that is adjacent to a second side surface of the LED pump die and opposite the first dielectric mirror, the second dielectric mirror being configured to reflect light within the first wavelength range and transmit light within the second wavelength range.

13. The LED package of claim 12, wherein the second dielectric mirror reflects light within the first wavelength range emitted from the LED package back into the LED package.

14. A method for producing an LED package, the method comprising:
disposing an LED pump die on a substrate, the LED pump die configured to emit light within a first wavelength range;
encapsulating the LED pump die in a phosphor having characteristics that convert light within the first wavelength range to light within a second wavelength range, the second wavelength range being higher than the first wavelength range; and
placing a dielectric mirror opposite a surface of the LED pump die from which light is emitted, the dielectric mirror being configured to reflect light within the first wavelength range and transmit light within the second wavelength range.

15. The method of claim 14, wherein the first wavelength range is 350-500 nm and the second wavelength range is 600-2500 nm.

16. The method of claim 14, wherein a majority of light emitted is emitted from a first surface of the LED pump die.

17. The method of claim 16, wherein the dielectric mirror is placed over the first surface of the LED pump die.
